(19) United States
(12) Patent Application Publication
(10) Pub. No.: US 2008/0299466 A1
(43) Pub. Date: Dec. 4, 2008

(54) ALTERNATIVE PHASE-SHIFTING MASK AND MANUFACTURING METHOD THEREOF

(75) Inventor: Takashi INOUE, Sagamihara-shi (JP)

Correspondence Address: YOUNG & THOMPSON, 209 Madison Street, Suite 500, ALEXANDRIA, VA, 22314, US

(73) Assignee: NEC ELECTRONICS CORPORATION, Kanagawa (JP)

(21) Appl. No.: 12/131,266

(22) Filed: Jun. 2, 2008

(30) Foreign Application Priority Data
Jun. 1, 2007 (JP) 2007-146543

(51) Int. Cl. G03F 1/14

(52) U.S. Cl. 430/5

(57) ABSTRACT

A method of manufacturing an alternative phase-shifting mask, includes forming first and second patterns on a transparent substrate to be adjacent to each other, the first and second patterns are transmittable and the second pattern having a recessed portion of the substrate for phase-shifting. A laser light is irradiated to sidewall portions of the recessed portion to modify the sidewall portions such that a transmittance of the sidewall portions to exposure light is lower than that of a bottom portion of the recessed portion.

### INCORPORATION BY REFERENCE

This patent application is based on Japanese Patent Application No. JP2007-146543. The disclosure thereof is incorporated herein by reference.

### BACKGROUND OF THE INVENTION

1. Field of the Invention

The present invention relates to an alternative phase-shifting mask and a method of manufacturing an alternative phase-shifting mask.

2. Description of Related Art

As a photo-mask for a micro process of a semiconductor wafer is known a Levenson mask, i.e., alternative phase-shifting mask, which is a kind of phase-shifting mask. The alternative phase-shifting mask is a photo-mask with improved transfer characteristics by improving resolution and depth of focus through control of the phase of light. In order to control a phase difference, a recessed portion is formed in one of adjacent patterns disposed closely to change an optical path length.

FIG. 1 is a cross-sectional view showing a typical alternative phase-shifting mask. The alternative phase-shifting mask 101 includes a first pattern 104 and a second pattern 105 which are provided in a light shielding film 103 disposed on a transparent substrate (e.g. quartz glass plate) 102. The first pattern 104 allows light a1 to transmit. The second pattern 105 is provided in the vicinity of the first pattern 104 and allows light b1 to transmit. The second pattern 105 has a recessed portion 106 which is formed by excavating the substrate 102 and used for phase-shifting. The light a1 which has transmitted the substrate 102 transmits the first pattern 104 and is emitted as light a2. In contrast, the light b1 which has transmitted the substrate 102 transmits the second pattern 105 and is emitted as light b2. The phase of the light a1 is equal to that of the light b1 in the substrate 102. However, a transmission distance of the substrate 102 in the light b1 is shorter than that of the light a1 for the recessed portion 106. Accordingly, the phase of the light b2 having transmitted the second pattern 105 differs from that of the light a2 having transmitted the first pattern 104 by about 180 degrees. Therefore, a resolution and a focus depth are improved so that transfer characteristics are improved.

Here, in the first pattern 104 of the above alternative phase-shifting mask 101, light c is made incident from the periphery thereof in addition to the light a1 at the time of exposure. However, the light c does not cause any problem with respect to the emission of the light a2 because their phases are aligned on the surface of the substrate 102.

On the other hand, on a bottom surface 109 of the recessed portion 106 of the second pattern 105, light d1 which is made incident from the periphery thereof in addition to the light b1. However, the light d1 does not cause any problems with respect to the emission of the light b2 because their phases are aligned on the bottom surface 109. However, when light d2 has transmitted the sidewalls 107 of the recessed portion 106 of the second pattern 105 and is emitted as light d3, the phase of the light d2 on the sidewalls 107 differs from that of the light b1 on the bottom surface 109, which causes the phase of the light b2 to be deviated from a predetermined phase. That is, the light b2 whose phase should differ from that of the light a2 by about 180 degrees will result in having a phase for a deviation different from the deviation of the 180 degrees. When such light b2 reaches the surface of a semiconductor wafer, defects of generating deterioration of the focus depth and resolution are observed in the semiconductor wafer. Therefore, a technique to suppress the light d3 from the sidewalls 107 is desired.

As a related technique, Japanese Patent Application Publication (JP-P2000-81696A) discloses a phase-shifting mask and a manufacturing method thereof. In this phase-shifting mask, sidewalls of a recessed portion are covered with a light shielding film in a photo-mask in which the recessed portion is produced as a phase shift area of a transparent substrate. In the method of manufacturing the phase-shifting mask, a thin film and a resist film are sequentially formed on the transparent substrate, and the resist film is patterned to produce a pattern of the recessed portion. Then, the thin film is removed by using the pattern of the resist film as a mask, a portion of the transparent substrate corresponding to a removed portion of the thin film is removed to a predetermined depth in which the phase is shifted by 180 degrees, and the produced recessed portion is filled with a light shielding material which differs from a material used in the thin film. Then, a film of the light shielding material is flattened to produce a light shielding film on an entire surface of the transparent substrate, and a resist film is produced on the light shielding film. Then, the resist film is patterned so that the light shielding film having a sufficient thickness to shield light is provided on sidewalls of the recessed portion, and the light shielding film and thin film are removed by using the pattern of the resist film as a mask.

Japanese Patent Application Publication (JP-A-Heisei 11-119411) discloses a phase-shifting mask and a manufacturing method thereof. This phase-shifting mask includes a light shielding portion made of a light shielding film, and light emitting patterns including a first pattern and a second pattern to be produced on a substrate which is transparent to exposure light. The first pattern is produced by excavating the substrate and the phase of light having transmitted the first pattern differs from that of light having transmitted the second pattern by about 180 degrees. In this phase-shifting mask, the first pattern has sidewalls formed with sidewall-like patterns, and the sidewall pattern or a light shielding film on the sidewall pattern dissipates or reduces the waveguide effect. Thus, a line width of a pattern transferred onto a material layer exposed with light which has transmitted the first pattern is substantially equalized to that with light which has transmitted the second pattern.

In the above methods to produce a light shielding film on sidewalls of a recessed portion (i.e. excavated portion of a substrate) as described in Japanese Patent Application Publications (JP-P2000-81696A and JP-A-Heisei 11-119411), the process of depositing the light shielding film onto the sidewalls is an extremely large burden in manufacturing the alternative phase-shifting mask. That is, for deposition of the light shielding film on the sidewalls of the recessed portion, it is necessary to first produce a mask pattern, deposit a light shielding film (e.g. chromium) on the entire surface of the mask and then perform drawing, developing and etching only to a portion of the sidewalls for the light shielding film to be left, after resist coating. These processes causes extension of a period to produce the mask, increase of a mask cost, and increase in a defect occurrence rate, imposing an extreme burden to manufacture the mask.

A technique is desired to appropriately suppress light incident from sidewalls of a recessed portion (i.e. excavated portion of a substrate) while suppressing the extension of a period to produce the mask, the increase of the mask cost, and the increase in the defect occurrence rate.

### SUMMARY

In an aspect of the present invention, a method of manufacturing an alternative phase-shifting mask, includes forming first and second patterns on a transparent substrate to be adjacent to each other, the first and second patterns are transmittable and the second pattern having a recessed portion of the substrate for phase-shifting. A laser light is irradiated to sidewall portions of the recessed portion to modify the sidewall portions such that a transmittance of the sidewall portions to exposure light is lower than that of a bottom portion of the recessed portion.

In another aspect of the present invention, an alternative phase-shifting mask includes a first pattern which light transmits; a second pattern which is provided in a vicinity of the first pattern, which the light transmits, and which has a recessed portion; and a modification section provided in a sidewall section of the recessed portion and having a transmittance to an exposure light lower than that of a bottom portion of the recessed portion to the exposure light.

The present invention makes it possible to appropriately suppress light radiated from sidewalls of a recessed portion (i.e. excavated portion of a substrate) in an alternative phase-shifting mask, where an improved resolution and depth of focus enable to enhance transfer characteristics.

### BRIEF DESCRIPTION OF THE DRAWINGS

The above and other objects, advantages and features of the present invention will be more apparent from the following description of certain embodiments taken in conjunction with the accompanying drawings, in which:

FIG. 1 is a cross-sectional view showing a typical alternative phase-shifting mask;

FIG. 2 is a cross-sectional view showing a structure of an alternative phase-shifting mask according to an embodiment of the present invention;

FIGS. 3A to 3I are cross-sectional views showing a method to manufacture the alternative phase-shifting mask according to an embodiment of the present invention; and

FIG. 4 is a cross-sectional view showing the method to manufacture the alternative phase-shifting mask according to the embodiment of the present invention.

### DESCRIPTION OF THE PREFERRED EMBODIMENTS

Hereinafter, a Levenson mask or an alternative phase-shifting mask and a manufacturing method thereof according to the present invention will be described with reference to the attached drawings.

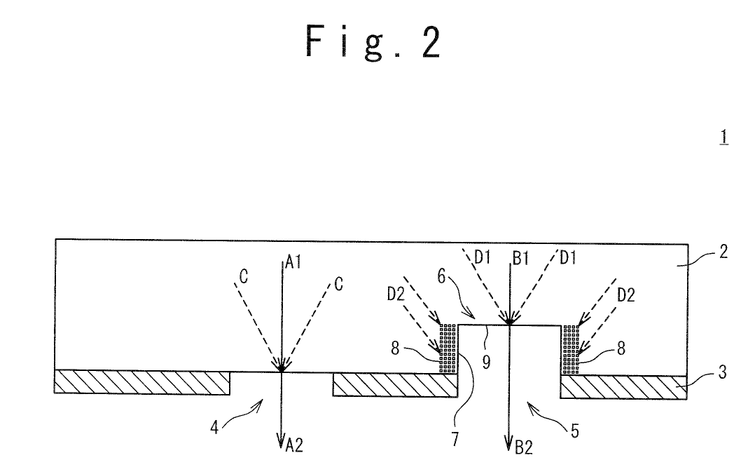

FIG. 2 is a cross-sectional view showing a structure of the alternative phase-shifting mask according to an embodiment of the present invention. The alternative phase-shifting mask 1 includes a first pattern 4, a second pattern 5 and transmission reduction sections 8.

The first pattern 4 is provided for a light shielding film 3 formed on a transparent substrate 2. The substrate 2 is exemplified by a quartz glass plate. The light shielding film 3 is exemplified by a chromium (Cr) film. Light A1 for exposure transmits the first pattern 4 from a side of the substrate 2 and is emitted toward an exposure object as light A2.

The second pattern 5 is produced in the vicinity of the first pattern 4 by the light shielding film 3 formed on the transparent substrate 2. The second pattern 5 has a recessed or concave portion 6 which is formed by excavating the substrate 2 and used for phase-shifting. Light B1 for exposure transmits through the second pattern 5 from the side of the substrate 2 and is emitted toward the exposure object as light B2.

The transmission reduction section 8 serving as a modified portion is provided on the surface or in internal portions (on a side of the substrate 2) of the sidewall portions 7 of the recessed portion 6 to lower the transmittance of exposure light in comparison with a bottom surface 9 of the recessed portion 6. The transmittance of exposure light is preferably 15% or less. It is therefore made possible to efficiently suppress light from the sidewall portions 7 of the recessed portion 6 and remove influence to the light B2.

The transmission reduction section 8 is produced by modifying a material of the substrate 2 in the sidewall portions 7. The transmission reduction section 8 can be provided as, for example, a group of fine voids formed in the internal portions of the sidewall portions 7. If such a group of voids are densely present, the exposure light which is about to pass through the sidewall portions 7 is scattered and reflected by the voids. Accordingly, transmission of the light is suppressed and the transmittance of the exposure light can be reduced. The distances among the plurality of voids preferably are a half of the wavelength of the exposure light or less. It is because this distance allows the light to be reflected and scattered efficiently. Arrangement of the plurality of voids in a 3-dimensional matrix form is preferable in terms of easiness to control forming of the voids by a laser as will be described later.

The transmission reduction section 8 may also be provided as, for example, a plurality of regions with different refractive indexes formed in the internal portions of the sidewall portions 7. Such a plurality of regions include adjacent regions whose boundary surfaces are directed to various directions. Therefore, the exposure light which is about to pass through the sidewall portions 7 is scattered and reflected on the multiple boundary surfaces. Transmission of the light is therefore suppressed and the transmittance of the exposure light can be reduced.

The transmission reduction section 8 can also be provided as, for example, a fine unevenness portion produced on the surfaces of the sidewall portions 7. Due to such a fine unevenness portion, the exposure light which is about to pass through the sidewall portions 7 is scattered and reflected on the surfaces of the sidewall portions 7 in the same manner as a case of a so-called fogging glass. The transmission of the light is therefore suppressed and the transmittance of the exposure light can be reduced.

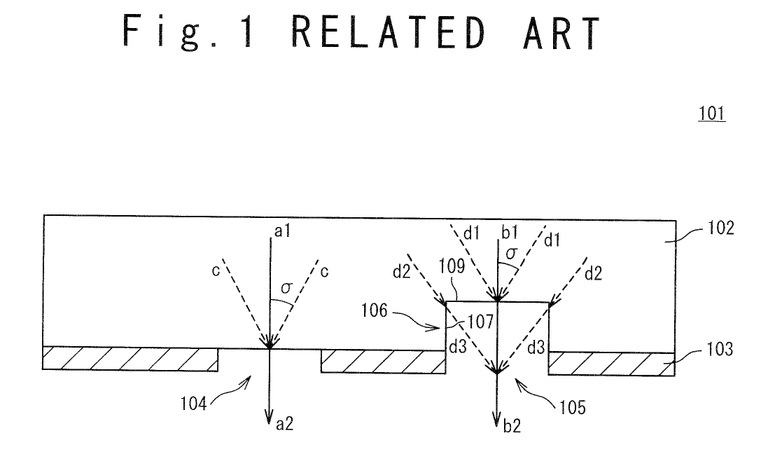

In the alternative phase-shifting mask 1, light C has been made incident into the first pattern 4 from the periphery thereof in addition to the light A1 at the time of exposure. However, the light C does not cause any problems with respect to the emission of the light A2 because these phases are aligned on the surface of the substrate 2. The bottom surface 9 of the recessed portion 6 of the second pattern 5 also has incidence of not only the light B1 but also light D1 radiated from the periphery thereof. However, the light D1 does not cause any problems with respect to the emission of the light B2 on the bottom surface 9 because these phases are aligned thereon. Also, there is a probability that the light D2 reaches the sidewall portions 7 of the recessed portion 6 of the second pattern 5 and transmits the sidewall portions 7. However, the present invention can prevent the light D2 which reaches the sidewall portions 7, from passing through the sidewall portions 7 by the transmission reduction sections 8 as stated above. That is, the light d1 in FIG. 1 can be substantially suppressed. Therefore, the light D2 and the light B1 which have different phases in the sidewall portions 7 and the bottom surface 9 are emitted to the second pattern 5 and interfered from one another to prevent a deviation of the phase of the light B2 from a desired phase. That is, a desired purpose of setting the phase of the light B2 to be different from the phase of the light A2 by about 180 degrees can be more certainly achieved. As a result, it is made possible to suppress deterioration of a depth of focus and a resolution in the semiconductor wafer.

Next, a method of manufacturing the alternative phase-shifting mask according to the embodiment of the present invention will be described below.

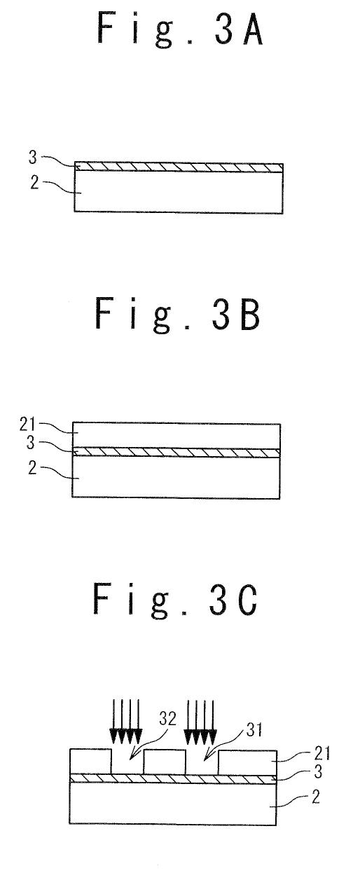

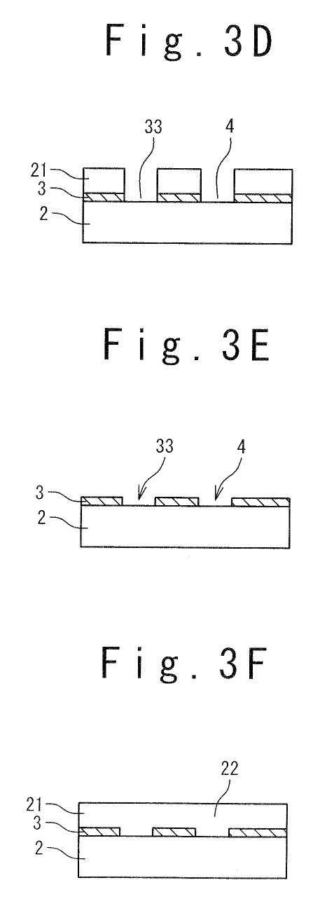

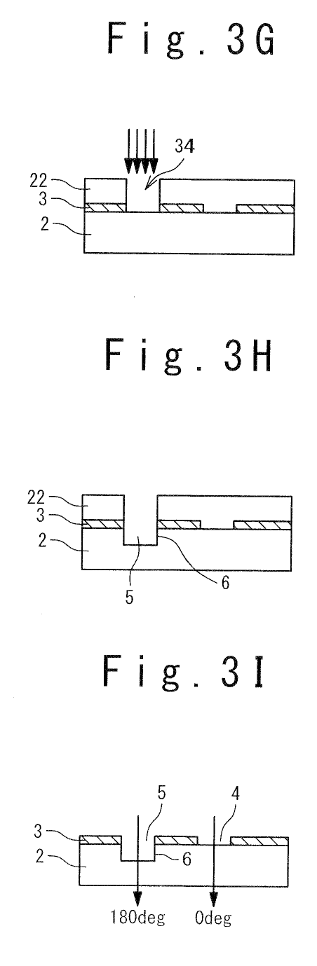

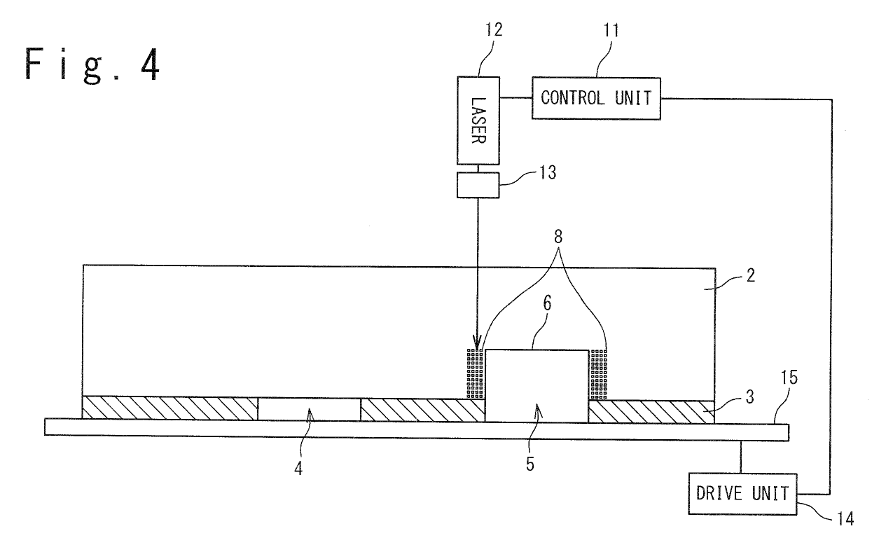

FIGS. 3A to 3I and 4 are cross sectional views showing the method to manufacture the alternative phase-shifting mask according to the embodiment of the present invention.

Referring to FIG. 3A, a chromium film serving as the light shielding film 3 is produced on a synthetic quartz glass plate serving as the substrate 2. Referring to FIG. 3B, a resist 21 is coated to cover the light shielding film 3. Referring to FIG. 3C, the resist 21 is subjected to exposure and development for patterning. Therefore, a pattern 31 is produced in a position for the first pattern 4 and a pattern 32 is produced in a position for the second pattern 5 in the resist 21. The light shielding film 3 is exposed in the pattern 31 and the pattern 32.

Referring to FIG. 3D, the light shielding film :3 is removed by etching in the pattern 31 and the pattern 32. Therefore, the first pattern 4 and a pattern 33 are produced in the light shielding film 3. The substrate 2 is exposed in the first pattern 4 and the pattern 33. Referring to FIG. 3E, the resist 21 which covers the light shielding film 3 is peeled off to expose the light shielding film 3. Referring to FIG. 3F, a resist 22 is coated so as to cover the light shielding film 3, the first pattern 4 and the pattern 33.

Referring to FIG. 3G, the resist 22 is subjected to patterning by performing exposure and development therein. Therefore, a pattern 34 is produced in a position for the second pattern 5 in the resist 22. The substrate 2 is exposed in the pattern 34. Referring to FIG. 3H, the substrate 2 in the pattern 34 is subjected to etching to a predetermined depth. Therefore, the second pattern 5 having the recessed portion 6 is produced in the light shielding film 3 and the substrate 2. The side surfaces and the bottom surface of the recessed portion 6 are exposed in the second pattern 5. Referring to FIG. 3I, the resist 22 which covers the light shielding film 3 and the first pattern 4 is peeled off to expose the light shielding film 3 and the first pattern 4. The depth of the recessed portion 6 is set so that, when light having the same phase transmits the first pattern 4 and the second pattern 5, the phase of light having transmitted the first pattern 4 is deviated from that of light having transmitted the second pattern 5 by about 180 degrees due to the difference in the optical path length.

Any manufacturing method may be employed as far as a mask has a structure identical to that of the mask shown in FIG. 3I.

Referring to FIG. 4, a laser is irradiated to the internal portions or surfaces of the sidewall portions of the recessed portion 6 from a side opposite to the light shielding film 3 with respect to the substrate 2. Therefore, the glass is damaged selectively in predetermined portions, where the damaged portions are modified to produce the aforementioned transmission reduction section 8.

In FIG. 4, a device to manufacture the transmission reduction section 8 is provided with a control unit 11, a laser 12, an optical system 13, a stage driving unit 14, and an X-Y stage 15.

The substrate 2 is located on the X-Y stage 15. The driving unit 14 moves the X-Y stage 15 to a desired position. Accordingly, if a relatively large movement of the substrate 2 is desired, the driving unit 14 is used to realize the movement. The laser 12 irradiates laser light toward the substrate 2. Details will be described later. The optical system 13 controls an irradiation position (focus position) of the laser light. It is therefore made possible to irradiate the laser light while minutely moving the focus in a fine area. The control unit 11 controls the laser light to be irradiated on a desired position of the sidewall portions of the recessed portion 6 by cooperating the laser 12, the optical system 13 and the driving unit 14.

The laser 12 is more preferably a femto-laser, for example. The femto-laser is an optical laser which is capable of emitting light only from several femtoseconds (i.e. 2-3×10⁻¹⁵ seconds) to several-hundred femtoseconds. For selective modification in the sidewall portions 7 of the recessed portion 6, extremely fine regions need to be irradiated in high accuracy by the laser light. It is also necessary to avoid modification in regions which modification is not required. The femto-laser is capable of limiting its energy to a small amount by narrowing a region irradiated with a single pulse of the laser light. It is therefore made possible to change a refractive index of the substrate 2 by changing the structure of the substrate 2 in a narrow region in the vicinity of the focus without affecting peripheral regions. Accordingly, the transmission reduction section 8 can be controlled to have desired characteristics.

In case of forming a plurality of voids (i.e. transmission reduction sections 8) in a synthetic quartz glass plate (i.e. substrate 2), one pulse of a laser light having the wavelength of 700 to 900 nm (more preferably 800 nm), the energy of 4 to 12 μJ (more preferably 8 μJ) and the duration of 100 to 900 femtoseconds is irradiated to produce a single void. The plurality of voids are preferably produced in a layer form to be arranged as parallel planes to the sidewall portions 7 for easy process control and easy transmittance control. The 3-dimensional and regular arrangement of the voids makes position control easy in a laser process. Depending on the number of layers and the density of the voids in a single layer, the transmittance can also be easily controlled.

Through the above process the alternative phase-shifting mask 1 according to the present invention is manufactured.

The transmission reduction portions are arranged in the sidewall portions by using the aforementioned manufacturing process with the Laser in the present invention, which makes it possible to produce the alternative phase-shifting mask easily and in a short period in comparison with a case of producing the light shielding film on the sidewalls. It is possible to appropriately suppress light radiated from the sidewalls of the recessed portion (i.e. excavated portion of the substrate) while suppressing an extension of a period to produce the mask, an increase of mask cost, and an increase in the defect occurrence rate or the like.

According to the present invention, light radiated from the sidewalls of the recessed portion (i.e. excavated portion of the substrate) in the alternative phase-shifting mask can be appropriately suppressed, where an improvement of resolution and depth of focus makes it possible to improve transfer characteristics.

The present invention is not limited to each of the above embodiments, and it is apparent that each of the embodiments can be appropriately modified or changed within the scope of technical ideas of the present invention.

What is claimed is:

1. A method of manufacturing an alternative phase-shifting mask, comprising:
forming first and second patterns on a transparent substrate to be adjacent to each other, said first and second patterns are transmittable and said second pattern having a recessed portion of said substrate for phase-shifting; and
irradiating a laser light to sidewall portions of said recessed portion to modify said sidewall portions such that a transmittance of said sidewall portions to exposure light is lower than that of a bottom portion of said recessed portion.

2. The method according to claim 1, wherein said irradiating comprises:
forming a plurality of voids in said sidewall portions with said laser light.

3. The method according to claim 2, wherein said forming a plurality of voids comprises:
forming said plurality of voids in a 3-dimensional matrix, and
wherein a distance between two of said plurality of voids is a half of a wavelength of the exposure light or less.

4. The method according to claim 1, wherein said irradiating comprises:
forming a plurality of regions whose refractive index is different from that of said transparent substrate, in said sidewall portions with said laser light.

5. An alternative phase-shifting mask comprising:
a first pattern which light transmits;
a second pattern which is provided in a vicinity of said first pattern, which the light transmits, and which has a recessed portion; and
a modification section provided in a sidewall section of said recessed portion and having a transmittance to an exposure light lower than that of a bottom portion of said recessed portion to the exposure light.

6. The alternative phase-shifting mask according to claim 5, wherein said modification section has a plurality of voids provided for said sidewall section.

7. The alternative phase-shifting mask according to claim 6, wherein said plurality of voids are arranged in a 3-dimensional matrix, and
wherein a distance between two of said plurality of voids is a half of a wavelength of the exposure light or less.

8. The alternative phase-shifting mask according to claim 5, wherein said modification section comprises a plurality of regions whose refractive index is different from that of said transparent substrate, and which are provided in said sidewall section.

9. The alternative phase-shifting mask according to claim 5, wherein a transmittance of said modification section to the exposure light is 15% or less.
